(19) United States
(12) Patent Application Publication
(10) Pub. No.: US 2011/0228475 A1
(43) Pub. Date: Sep. 22, 2011

(54) ENCLOSURE WITH CONCURRENTLY MAINTAINABLE FIELD REPLACEABLE UNITS

(75) Inventors: William James Anderl, Rochester, MN (US); Philip M. Corcoran, Highland, NY (US); Edward J. Seminaro, Milton, NY (US)

(73) Assignee: International Business Machines Corporation, Armonk, NY (US)

(21) Appl. No.: 12/725,620

(22) Filed: Mar. 17, 2010

(51) Int. Cl. H05K 7/20

(52) U.S. Cl. 361/691; 361/692

(57) ABSTRACT

An electronic system enclosure including cooling units to regulate temperature of electrical components therein. In one embodiment, the electronic system enclosure includes field replaceable units which facilitate concurrent maintenance. In this embodiment, air pressure within the electronic system enclosure is maintained while a field replaceable unit is removed. Also in this embodiment, cooling of the remaining electrical components of the electronic system enclosure is continued during removal of a field replaceable unit.

### BACKGROUND

The present invention relates to an electronic system enclosure, and, more specifically, relates to an enclosure having a first removable unit and a second removable unit that may include power supplies and cooling fans.

Electronic system enclosures may include cooling systems to regulate the temperature of their electrical components. One type of cooling system is a forced air system that relies on a plurality of air movers to blow air over the electrical components in order to cool the components. Replacement of a failed cooling unit or performing maintenance on the electrical components involves the extraction of the power supply from the electronic system enclosure.

### SUMMARY

An example embodiment of the present invention is an electronic system enclosure which includes a plurality of field replaceable enclosures. The field replaceable enclosures include side vents. Also included in the electronic system enclosure is a plurality of biased flaps attached to the electronic system enclosure below the field replaceable enclosures. When one of the field replaceable enclosures is removed from the electronic system enclosure, the flaps are actuated into position and create an airflow path to a side vent of another field replaceable enclosure remaining in the electronic system enclosure. The embodiment may include a mid-plate located above the field replaceable enclosures. The mid-plate defines a top chamber in the electronic system enclosure. The mid-plate includes a plurality of openings configured to facilitate airflow from the top chamber to the field replaceable enclosures.

The example embodiment may further include two flaps. The first flap and the second flap are actuated in tandem when one of the field replaceable enclosures is removed from the electronic system enclosure. In this example configuration the first flap is configured to substantially prevent airflow from directly entering the side vent of the field replaceable enclosure remaining in the electronic system enclosure. The second flap is configured to substantially prevent positively pressurized airflow from circulating back into the second field replaceable enclosure remaining in the electronic system enclosure through the side vent.

Further, the field replaceable enclosures of the example embodiment may include cooling fans that are configured to provide airflow throughout the electronic system enclosure. The field replaceable enclosures may also include power supplies.

Another example of the embodiment of the present invention is an electronic system enclosure which includes a plurality of field replaceable enclosures which include side vents. The example electronic system enclosure also includes a plurality of flaps attached to the electronic system enclosure above the field replaceable enclosures. The flaps of the example electronic system enclosure are actuated when one of the field replaceable enclosures is removed from the electronic system enclosure. The actuated flaps create an airflow path to a side vent of another field replaceable enclosure remaining in the electronic system enclosure.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 shows an example electronic system enclosure including a plurality of field replaceable enclosures contemplated by the invention.

FIG. 2 shows an example electronic system enclosure with one of the field replaceable enclosures removed.

FIG. 3 shows a sectional view of electronic system enclosure with one of the field replaceable enclosures removed.

FIG. 4 shows a cross-sectional side view of an example electronic system enclosure with the first flap and second flap actuated to an upright position.

FIG. 5 shows a cross-sectional side view of a field replaceable enclosure partially inserted into the example electronic system enclosure with the second flap actuated to an upright position.

FIG. 6 shows a particular embodiment of the invention wherein the cooling fans in the field replaceable enclosures embodied as a counter-rotating fan housing two independent rotors.

FIG. 7 shows an alternative example of the electronic system enclosure where the flaps are positioned above the field replaceable enclosures hinged from the top of the electronic system enclosure.

### DETAILED DESCRIPTION

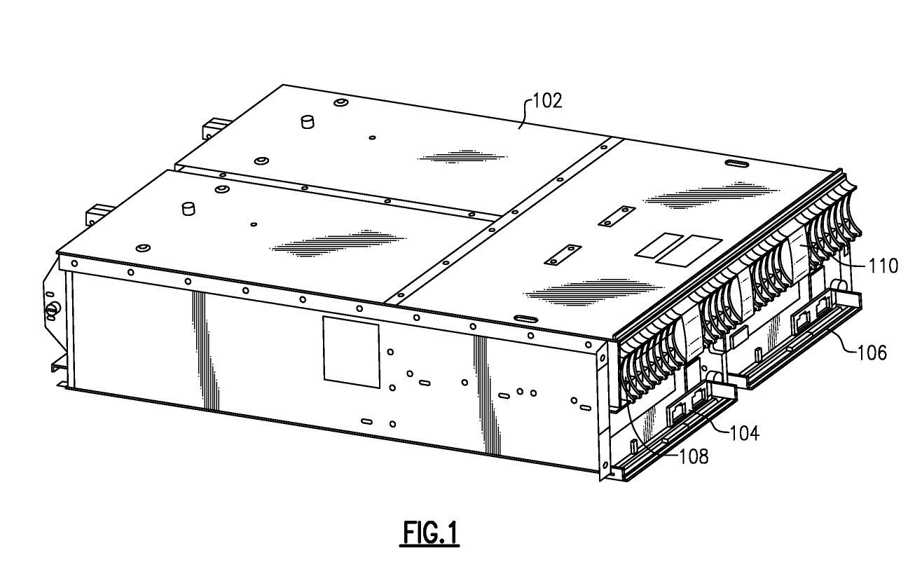

The present invention is described with reference to embodiments of the invention. Throughout the description of the invention reference is made to FIGS. 1-7.

Aspects of the invention relate to equipment placed in a server rack. For example, once the electronic enclosure is placed in the server rack it can typically be accessed from either the front or the back to perform service; all other internal components are generally inaccessible. There is usually little room in the front and the back compared to the amount of components in the electronic enclosure. Cool airflow, air pressure and power should be maintained throughout the electronic enclosure when the enclosure is inserted in the rack and when a field replaceable unit is extracted for maintenance or repair.

The challenge is to use a minimum number of fans necessary for cooling. It is important to keep the use of the cooling fans to a minimum because cooling fans tend to be noisy, expensive and failure prone. Also, it is beneficial to have the fans in a location such that if some of the fans break, they can be replaced while maintaining functionality of and power to the enclosed equipment. For example, positioning the cooling fans in a field replaceable unit, as opposed to behind disk drives, can have an added benefit of not requiring the removal of the disk drives to access the cooling fans. Also, hard drives may be serviced in place reducing potential errors to the hard drives caused by removal.

FIG. 1 illustrates an example electronic system enclosure 102 contemplated by the invention. In one embodiment, the electronic system enclosure 102 is a rack-mount device designed to be rack-mounted in a standardized frame or enclosure. The electronic system enclosure 102 may be constructed from sheet metal, plastic and/or other suitable materials known by those skilled in the art. The electronic system enclosure 102 includes a plurality of field replaceable enclosures 104 and 106.

As discussed in more detail below, the field replaceable enclosures 104 and 106 may be removed and reinserted into the electronic system enclosure 102 by actuating a handle which disengages the field replaceable enclosure permitting them to be slid in and out. Removal of a field replaceable enclosure can facilitate access and service of components within the field replaceable enclosure, as well as the electronic system enclosure 102.

In a particular embodiment, the electronic system enclosure 102 includes an array of storage units 108. The storage units 108 may, for example, include hard drives, tape drives, or other devices for storing computer data. The electronic system enclosure 102 may further include assembly port expander cards embedded with storage unit control electronics 110 located between the storage units 108. As discussed below, the field replaceable enclosures 104 and 106 may include power supplies configured to supply power in a redundant manner to the storage units 108 and other devices in the electronic system enclosure 102.

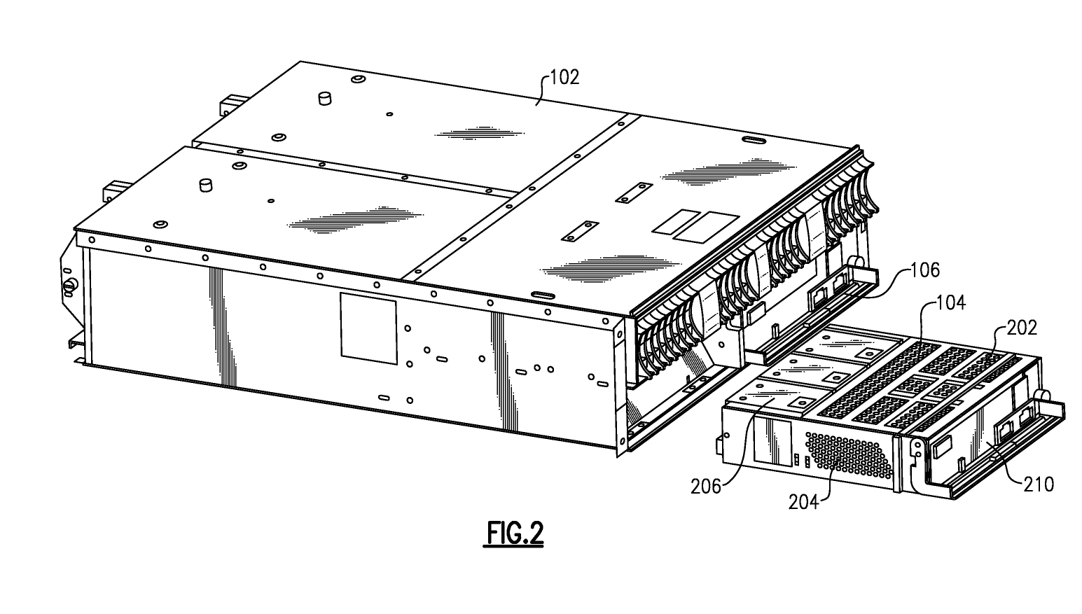

Turning now to FIG. 2, the electronic system enclosure 102 is shown with one of the field replaceable enclosures 104 removed. As shown, each field replaceable enclosure 104 may include one or more cooling fans 206. The cooling fans 206 are configured to provide airflow throughout the electronic system enclosure 102. For example, the cooling fans 206 can create a top to bottom airflow, drawing air down from above the field replaceable enclosure 104 and circulating the air within the electronic system enclosure 102. In a particular embodiment, the cooling fans 206 may be replaced or repaired by removing a field replaceable enclosure 104 and extracting the cooling fans 206. As detailed further below, the fans may be of the counter rotating variety 206.

Each field replaceable enclosure 104 and 106 may include a top vent 202 and side vents 204. The top vent 202 is configured to facilitate airflow from a top chamber into the field replaceable enclosures. In one embodiment, the top vent 202 may include a series of openings to facilitate circulation of air throughout the electronic system enclosure.

The side vents 204 of the field replaceable enclosure 104 allow airflow due to the cooling fans 206 to enter the field replaceable enclosure 104. Each field replaceable enclosure has at least one side vent 204. In one embodiment, each field replaceable enclosure includes a left side vent 204 and a right side vent 204. In one embodiment, the side vents 204 may include a series of openings to facilitate circulation of air throughout the electronic system enclosure.

Each field replaceable enclosure 104 may include one or more power supplies 210. The power supplies 210 are electrically coupled in parallel circuit such that power is maintained without interruption to other devices in the electronic system enclosure when one of the field replaceable enclosures is removed from the electronic system enclosure 102.

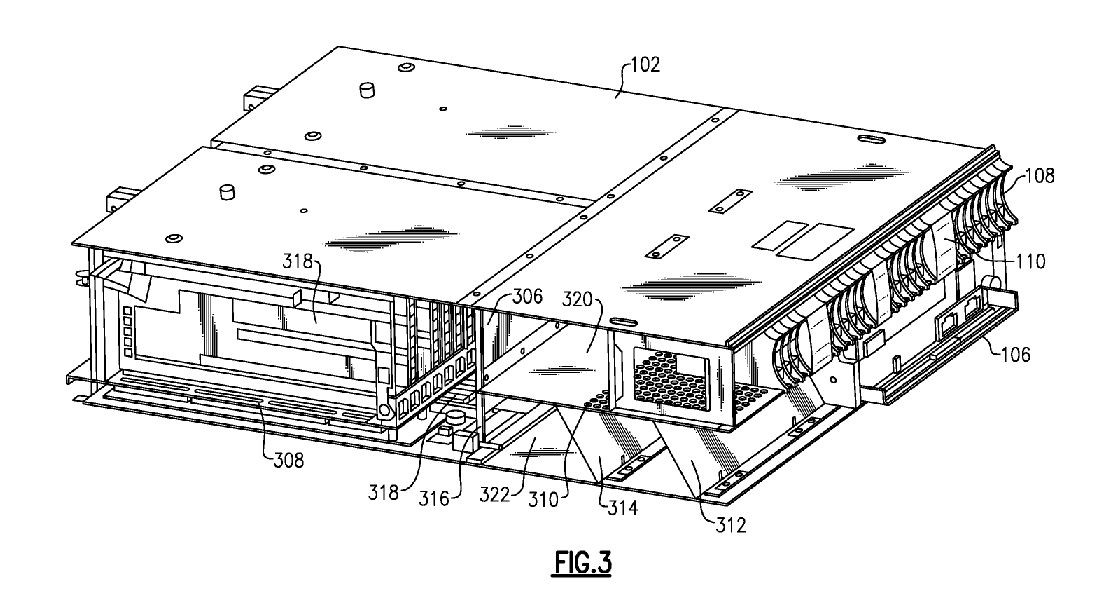

FIG. 3 shows a sectional view of the electronic system enclosure 102 with one field replaceable enclosure removed. The electronic system enclosure 102 includes a mid-plate 310 above the field replaceable enclosures 104 and 106. The mid-plate 310, along with a back wall 306, define an upper chamber 320 within the electronic system enclosure 102. The mid-plate 310 further comprises a plurality of openings which are configured to facilitate airflow from the top chamber 320 to the field replaceable enclosures 104 and 106. As mentioned above, the top chamber 320 may contain, for example, disk drives 108 and card assembly port expander cards embedded with storage unit control electronics 110 located between the storage units 108.

The cooling fans 206 of the field replaceable enclosure 104 create top to bottom airflow. Air is drawn down from above the field replaceable enclosures 104, through the openings of the mid-plate 310, and is then circulated through rest of the electronic system enclosure 102.

The system enclosure 102 may further include a back chamber 318 behind the field replaceable enclosures 104 and 106. In one embodiment, the back chamber 318 includes a plurality of PCI slots 308. The PCI slots may be used for connecting PCI circuit boards in the electronic system enclosure 102.

Airflow throughout the electronic system enclosure 102 is further facilitated through the PCI slots 308 which are located downstream from the airflow path exiting the field replaceable enclosures 104. Front to back airflow may be maintained throughout the field replaceable enclosure 102. Air is pulled into the field replaceable enclosure 104 and exits the rear of the electronic system enclosure 102 in parallel.

As shown, the electronic system enclosure 102 includes a plurality of spring loaded flaps 312 and 314, located beneath the field replaceable enclosures 104 and 106 when the field replaceable enclosures 104 are installed. In one embodiment, the field replaceable enclosures 104 may include a first flap 312 and a second flap 314. The electronic system enclosure 102 further includes an airflow wall 316 behind the field replaceable enclosures 104 and 106. The airflow wall includes a series of openings allowing air to pass.

On removal of a field replaceable enclosure 104, flaps 312 and 314 are actuated into an upright position. When flaps 312 and 314 are in the upright position, an air channel is formed with suction through the side vent of the remaining field replaceable enclosure. This suction allows the remaining field replaceable enclosure 106 to cool the entire electronic system enclosure 102 without disrupting operation of devices in the electronic system enclosure 102.

Actuated flaps 312 and 314 may form a uniform pressure region or plenum 322 in front of PCI cards 306. Cooling of the electronic system enclosure 102 may be maintained even with the field replaceable enclosure 104 and the corresponding power supply 210 removed. Thus, the flaps 312 and 314 beneficially maintain cool airflow and positive pressure throughout the field replaceable enclosure 102 even when one of the field replaceable enclosures is removed.

In one embodiment of the invention, the electronic system enclosure 102 includes a first flap 312 and second flap 314 below each field replaceable enclosure. The first flap 312 and second flap 314 are actuated in tandem when a field replaceable enclosure is removed from the electronic system enclosure 102.

The first flap 312 is configured to substantially prevent airflow from directly entering the side vent of the remaining field replaceable enclosure 106 without first entering the top chamber 320. The second flap 314 is configured to substantially prevent positively pressurized airflow of the plenum 322 from recirculating back into the second field replaceable 106 enclosure through the side vent 204 of the remaining field replaceable enclosure 106.

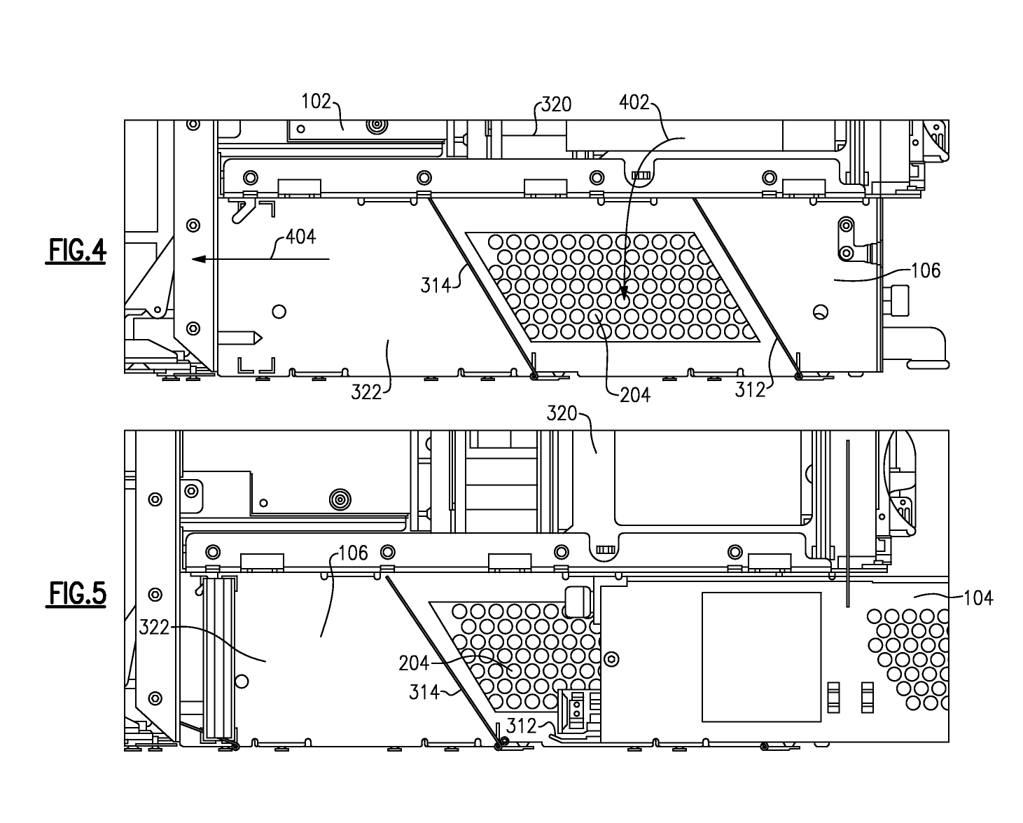

FIG. 4 shows a cross-sectional side view of the electronic system enclosure 102 with the first flap 312 and second flap 314 actuated to an upright position. As discussed above, the first flap 312 is configured to substantially prevent airflow 402 from directly entering the side vent of the remaining field replaceable enclosure 106 without first entering the top chamber 320. Furthermore, the second flap 314 is configured to substantially prevent positively pressurized airflow 404 within the plenum 322 from circulating back into the second field replaceable enclosure through the side vent 204 of the remaining field replaceable enclosure 106. It is noted that the parallelogram shape of the side vent 204 is completely enclosed by the channel created between the first flap 312 and second flap 314 actuated in the upright position.

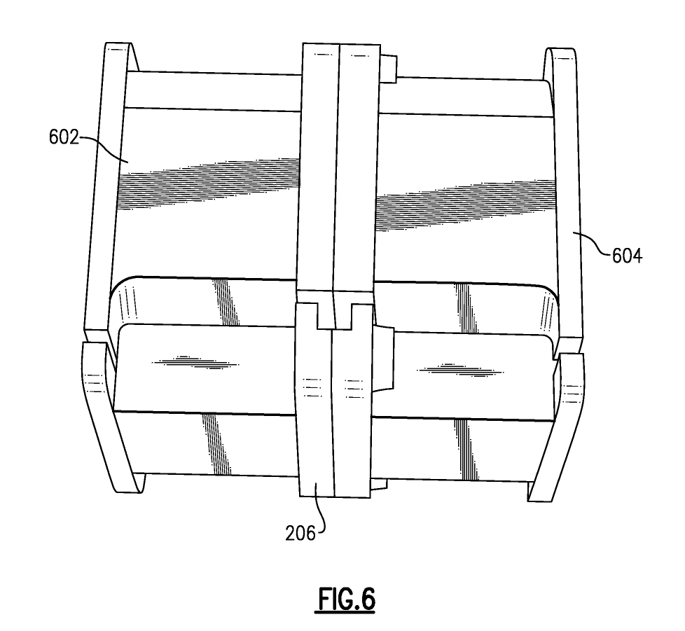

FIG. 5 shows a cross-sectional side view of a field replaceable enclosure 104 partially inserted into the electronic system enclosure 102. In this position, it can be seen that flaps 312 and 314 can work independently of each other. The second flap 314 is actuated into position by the removal of the first field replaceable enclosure 104, which substantially prevents airflow from the plenum 322 from entering the side vent 204 of the remaining second field replaceable enclosure 106. Thus, the plenum 322, partially defined by the second flap 314, stays pressurized such that there is no backflow into the remaining second field replaceable enclosure 106 through its side vent 204.

Flaps 312 and 314 not only block backflow. Actuated flaps 312 and 314 also redirect airflow to continue cooling components of the electronic system enclosure 102. The actuated flaps 312 and 314 create a negatively pressurized region which draws air from components upstream of the airflow path (i.e., in the top chamber 320) entering the remaining second field replaceable enclosure 106.

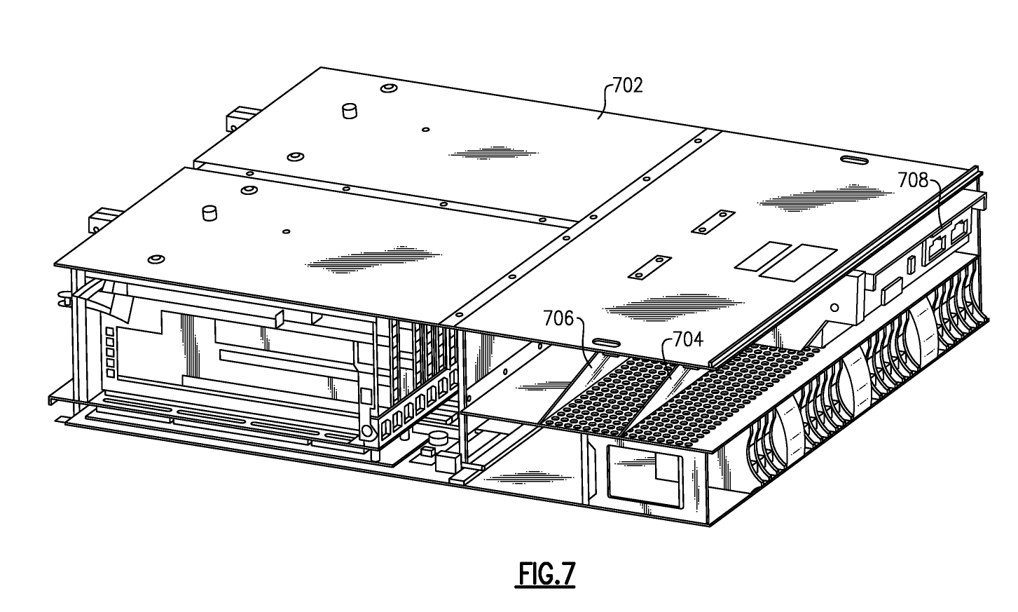

FIG. 6 shows a particular embodiment of the invention wherein the cooling fans 206 in the field replaceable enclosures are embodied as a counter-rotating fan housing two independent rotors. In this embodiment, a cooling fan 206 is comprised of a first rotor in its own housing 602 and a second rotor in its own housing 604. It is further contemplated that the first rotor 602 and the second rotor are independent of each other. For example, each rotor 602 and 604 includes a separate power supply and control mechanism to reduce the chances that both rotor 602 and 604 will fail at the same time. In this configuration, if either the first rotor 602 or the second rotor 604 fails, circulation of cool air is maintained in the electronic system enclosure 102 without backflow. This can be accomplished because one of the cooling rotor remains operable, thus preventing air recirculation back to the field replaceable enclosure 104.

The cooling rotor may be positioned such that the air exiting the first rotor 602 enters the second rotor 604. Also, the first rotor 602 is configured to rotate in the opposite direction of the second rotor 604, thereby reducing turbulence and amplifying airflow. Further, space is saved by the ability of placing the rotor closely next to each other.

In FIG. 7, an alternative embodiment of the electronic system enclosure 702 is shown. In this embodiment, the flaps 704 and 706 are positioned above the field replaceable enclosures 708 and can be actuated, for example, by gravity. As discussed above, when one of the field replaceable enclosures 708 is removed from the electronic system enclosure 702 the flaps 704 and 706 create an airflow path to a side vent of another field replaceable enclosure 708 remaining in the electronic system enclosure 702.

While the preferred embodiments to the invention have been described, it will be understood that those skilled in the art, both now and in the future, may make various improvements and enhancements which fall within the scope of the claims which follow. For example, the electronic system enclosure described above may be used to house and power many types of electronic devices, not only I/O and disk drive devices. Thus, the claims should be construed to maintain the proper protection for the invention first described.

What is claimed is:

1. An electronic system enclosure comprising:
a plurality of field replaceable enclosures, the field replaceable enclosures include side vents; and
a plurality of biased flaps attached to the electronic system enclosure below the field replaceable enclosures such that when one of the field replaceable enclosures is removed from the electronic system enclosure the flaps create an airflow path to a side vent of another field replaceable enclosure remaining in the electronic system enclosure.

2. The electronic system enclosure of claim 1, wherein the flaps are spring loaded.

3. The electronic system enclosure of claim 1, wherein the flaps are actuated with the removal of one field replaceable enclosure device.

4. The electronic system enclosure of claim 1, further comprising a mid-plate above the field replaceable enclosures defining a top chamber in the electronic system enclosure, the mid-plate including a plurality of openings configured to facilitate airflow from the top chamber to the field replaceable enclosures.

5. The electronic system enclosure of claim 4, wherein the field replaceable enclosures include top vents configured to facilitate airflow from the top chamber into the field replaceable enclosures.

6. The electronic system enclosure of claim 4, further comprising a plurality of storage units within the top chamber.

7. The electronic system enclosure of claim 4, further comprising a plurality of card assembly port expander drives.

8. The electronic system enclosure of claim 4, further comprising a back wall defining the top chamber.

9. The electronic system enclosure of claim 1, further comprising a plurality of PCI slots located downstream from the airflow path exiting the field replaceable enclosures.

10. The electronic system enclosure of claim 1, wherein the flaps, when actuated, prevent recirculation of air in a first field replaceable enclosure through an opening in the electronic system enclosure created by extraction of a second field replaceable enclosure from the electronic system enclosure.

11. The electronic system enclosure of claim 1, further comprising:
wherein the flaps include a first flap and a second flap actuated in tandem when a first field replaceable enclosure is removed from the electronic system enclosure;
wherein the first flap is configured to substantially prevent airflow from directly entering the side vent of the field replaceable enclosure remaining in the electronic system enclosure the electronic system enclosure due to removal of the first field replaceable unit from the electronic system enclosure; and
wherein the second flap is configured to substantially prevent positively pressurized airflow from circulating back into the second field replaceable enclosure through the side vent of the second field replaceable enclosure.

12. The electronic system enclosure of claim 11, wherein the second flap defines a plenum configured to sustain air pressure within the electronic system enclosure.

13. The electronic system enclosure of claim 1, wherein a negatively pressurized region is created between the flaps when the flaps are actuated, the negatively pressurized region drawing air from components upstream the airflow path entering the field replaceable enclosures.

14. The electronic system enclosure of claim 1, wherein the side vents of the field replaceable enclosure include a series of openings to facilitate circulation of air throughout the electronic system enclosure.

15. The electronic system enclosure of claim 1, wherein the field replaceable enclosures include cooling fans configured to provide airflow throughout the electronic system enclosure.

16. The electronic system enclosure of claim 15, wherein each of the cooling fans include a first fan and a second fan and positioned such that air exiting the first fan enters the second fan, the first fan is configured to rotate in an opposite direction to the second fan.

17. The electronic system enclosure of claim 15, wherein the cooling fans create a top to bottom airflow, drawing air down from above the field replaceable enclosure and circulating the air within the electronic system enclosure.

18. The electronic system enclosure of claim 1, wherein the field replaceable enclosures include power supplies.

19. The electronic system of claim 18, wherein the power supplies are electrically coupled in parallel circuit such that power is maintained without interruption to other devices in the electronic system enclosure when one of the field replaceable enclosures is removed from the electronic system enclosure.

20. An electronic system enclosure comprising:
a plurality of field replaceable enclosures, the field replaceable enclosures include side vents; and
a plurality of flaps attached to the electronic system enclosure above the field replaceable enclosures such that when one of the field replaceable enclosures is removed from the electronic system enclosure the flaps create an airflow path to a side vent of another field replaceable enclosure remaining in the electronic system enclosure.
